(19) United States
(12) Patent Application Publication
(10) Pub. No.: US 2018/0233649 A1
(43) Pub. Date: Aug. 16, 2018

(54) MAGNETIC HEAT POWER GENERATION DEVICE

(71) Applicant: CHUAN-DONG MAGNETIC ELECTRONIC CO., LTD., Foshan, Guangdong (CN)

(72) Inventors: Tian'an Zhao, Foshan, Guangdong (CN); Li Liu, Foshan, Guangdong (CN); Kewen Long, Foshan, Guangdong (CN)

(21) Appl. No.: 15/516,632

(22) PCT Filed: Jul. 15, 2015
(86) PCT No.: PCT/CN2015/084088

§ 371 Date: Apr. 3, 2017

(30) Foreign Application Priority Data
Jan. 14, 2015 (CN) 201510018930.4
Jul. 15, 2015 (CN) PCT/CN2015/084088

(51) Int. Cl. H01L 37/04

(52) U.S. Cl. CPC H01L 37/04

(57) ABSTRACT

A magnetic heat power generation device; a magnetic heat power generation unit comprises two main supports that are correspondingly connected, and comprises a rotor, a stator and a heating and cooling device; the rotor comprises an annular support; even-numbered groups of hard magnetic fixing grooves are formed on each of two sides of the annular support; a plurality of magnet locking plates in one-to-one correspondence to the hard magnetic fixing grooves is disposed on the annular support; connection portions of one supporting beam and the main supports are provided with adjusting grooves; mounting brackets are disposed on the adjusting grooves; the mounting brackets are provided with stationary retention magnets; a heat insulation plate is disposed on each of two sides of the connection portion of a mounting plate and a transfer arm of the heating and cooling device.

### TECHNICAL FIELD OF THE INVENTION

The present invention relates to the technical field of magnetic heat machines, and more particularly, to a magnetic heat power generation device.

### BACKGROUND OF THE INVENTION

A magnetic heat power generation device is capable of turning thermal energy into magnetic energy, through which magnetic energy can be further converted into mechanical energy to generate electricity. The traditional magnetic heat power generation device usually comprises a stator, which is provided with soft magnets, a rotor, which is provided with hard magnets, and a heating and cooling system which can heat and cool the soft magnets in the stator.

The structure of traditional magnetic heat power generation devices leads to the following shortcomings: First, in a traditional heating and cooling system, the soft magnets in the stator are respectively heated and cooled by a heating device and a cooling device. This arrangement requires a cumbersome structure, complicated pipeline and low integration level. Furthermore, the heating and cooling efficiency is seriously restricted by the complicated pipeline, resulting in a poor heating and cooling performance. Specifically, the heat transmission in this configuration is badly affected and the heat energy conversion rate is very low. Second, the peak value of the magnetic force fluctuates as the magnetic force of the soft magnet varies. In order to improve the conversion rate, a greater initial torque must be generated when the magnetic force of the soft magnet reaches the set value, thereby enabling the rotor to propel the output shaft to rotate and generate electricity. Thus, a retention magnet group is provided to the rotor and the support, avoiding the rotor from rotating under a low power output; the stationary retention magnet is fixed on the support to correspond to the moving retention magnet on the rotor. However, the magnetic heat power generation device is a multi-unit linkage configuration, such that the retention stations of the rotors may be imprecise after assembly. Under such circumstances, the filtering resistance of the retention magnet group can be sharply decreased, further lowering the conversion rate of the traditional magnetic heat power generation devices. Third, the hard magnet is connected to the rotor through a shielding case. A plurality of hard magnet fixing grooves is disposed on the rotor, and the two sides of the fixing grooves on the inner wall of the rotor are provided with locking elastic pieces. Additionally, the inner side of the upper end portion of the locking elastic piece includes a locking hook, the two side edges of the shielding case is snapped into the fixing groove, and the outer end of the shielding case is fixed through the locking hook. Accordingly, the mounting location of the hard magnet is difficult to regulate or replace. Furthermore, snap connection strength is inadequate, leading to low structural stability. The difficulty in mold-making of the locking hook is increased, resulting in a high manufacturing cost.

In conclusion, the shortcomings of traditional magnetic heat power generation devices are urgent problems that need to be solved for those skilled in this field.

### SUMMARY OF THE INVENTION

The purpose of the present invention is to solve the technical problems relating to the unreasonable structure in the prior art, and provide a magnetic heat power generation device, which can precisely adjust the retention stations of the rotors, improve the heating and cooling speed of the soft magnets on the stator, enhance the heat energy conversion rate, simplify the overall structure, reduce the difficulty in mold-making of the rotor, and improve the structural stability.

To achieve the above purpose, the present invention adopts the following technical solution:

A magnetic heat power generation device comprises at least one magnetic heat power generation unit. The magnetic heat power generation unit comprises two main supports that are correspondingly connected, and comprises a rotor, a stator and a heating and cooling device. A shaft seat A is disposed on the main support, and a shaft seat B is disposed on the rotor. An accommodating chamber is formed between the two main supports, and the rotor is disposed within the accommodating chamber. A dynamic rotation shaft inserts into the shaft seat A and the shaft seat B, enabling the rotor to rotate within the accommodating chamber. The two stators are fixed on the main supports corresponding to the two sides of the rotor. The heating and cooling device is fixed on the main supports. One end of the dynamic rotation shaft is connected to the power generation equipment. The rotor comprises an annular support. The shaft seat B, which is disposed in the annular support, is concentrically disposed with the annular support. A plurality of supporting pieces is connected between the shaft seat B and the annular support. An even number of groups of hard magnet fixing grooves are disposed on each of the two sides of the annular support. A plurality of magnet locking plates in one-to-one correspondence to the hard magnet fixing grooves is disposed on the annular support. The magnet locking plate is provided with mounting holes, and a hard magnet shielding case is disposed in the hard magnet fixing groove. A fixing bolt is inserted into the mounting hole and connected to the hard magnet shielding case. The main support comprises two side supporting plates that are vertically disposed to correspond to each other. The lower portions of the two side supporting plates are connected through a connecting plate. The shaft seat A is disposed in the middle of a space formed by the two side supporting plates and the connecting plate. The shaft seat A is firmly connected to the side supporting plates or the connection plate through a plurality of supporting beams. The portion connecting one of the supporting beams and the main support is provided with an adjusting groove. A mounting bracket is disposed in the adjusting groove. The mounting bracket is provided with a stationary retention magnet. The outer edge of the rotor is provided with a plurality of retention holes. Moving retention magnets are disposed in the retention holes. The connection plate is provided with a connecting base, and a plurality of fluid inlets is disposed on the upper portion of the connection base. The lower portion of the connecting base is provided with a large-caliber fluid outlet, and the fluid outlet is respectively interconnected to a plurality of fluid inlets. The lower end of the connecting base is provided with a fluid outlet pipe that is connected to the fluid outlet. A plurality of fluid inlet pipes is disposed on the upper portion of the stator, and a plurality of fluid outlet pipes is disposed on the lower portion of the stator. The fluid outlet pipes are respectively connected to the fluid inlets on the connecting base. The heating and cooling device comprises a support body, a mounting plate and two transfer arms. The lower end of the support body is respectively connected to the lower ends of the two transfer arms. The two ends of the mounting plate are respectively connected to the upper ends of the two transfer arms. Consequently, the upper end of the support body, the two ends of the mounting plate and the two transfer arms form a triangular configuration. The two sides of the portion connecting the mounting plate and the transfer arms are respectively provided with a heat insulation plate. A limiting plate is disposed at the inner end of the heat insulation plate. Each of the two sides of the support body is provided with a valve cap. A plurality of fluid exits is disposed on the valve cap. The fluid exits on the valve cap are respectively connected to the fluid inlet pipes of the upper portion of the stator on the corresponding side.

In another aspect of the present invention, the even-numbered groups of hard magnet fixing grooves are arranged in a staggered manner. The magnet locking plate is a grooved rail structure having a U-shaped cross section. The two ends of the magnet locking plate are respectively connected to the inner wall and the outer wall of the annular support. The openings of the groove rail of any two adjacent magnet locking plates are oppositely disposed. The magnet locking plates positioned in the same direction and the hard magnet fixing grooves on one side of the annular support are arranged in pairs.

In another aspect of the present invention, the hard magnet fixing groove comprises an outer fixing groove and an inner fixing groove. The outer fixing groove and the inner fixing groove are respectively provided with an outer shielding case and an inner shielding case. The magnet locking plate is provided with an inner mounting hole and an outer mounting hole that respectively correspond to the outer shielding case and the inner shielding case. An accommodating space is formed between the outer fixing groove and the inner fixing groove. The stator can move within the accommodating space.

In another aspect of the present invention, the adjusting groove, which is arc-shaped, takes the shaft seat A having the same plane as the center. The two sides of the inner and outer edges of the adjusting groove are provided with guiding plates corresponding to the radian of the adjusting groove. The two sides of the inner end of the mounting bracket are provided with locating plates, and the outer side edges of the two locating plates are respectively disposed against the guiding plate on each side.

In another aspect of the present invention, the supporting beam having the adjusting groove is provided with a calibrated scale for interacting with the mounting bracket.

In another aspect of the present invention, the inner end surface of the mounting bracket is provided with a fixing screw-hole. A fixing bolt is inserted into the adjusting groove. The front end of the fixing bolt is inserted through the adjusting groove and connected to the fixing screw hole. An adjusting hole is disposed on the mounting bracket, and the center of the adjusting hole is on the radial line of the shaft seat A having the same plane. The stationary retention magnet, which is cylinder-shaped, is provided with outer threads for interacting with the adjusting hole.

In another aspect of the present invention, a hot fluid valve port, a cold fluid valve port and a circulating groove are formed on the support body. The portions connecting the mounting plate and the two transfer arms are respectively provided with a hot fluid entrance and a cold fluid entrance. A passage hole connecting the hot fluid valve port and the hot fluid entrance, and a passage hole connecting the cold fluid valve port and the cold fluid entrance are respectively formed on the two transfer arms.

In another aspect of the present invention, the circulating groove is frame-shaped, and the hot fluid valve port and the cold fluid valve port are respectively disposed at the two upper corners of the circulating groove. A flow-split plate is disposed in the middle of the upper portion of the circulating groove.

In another aspect of the present invention, the opening ends of the hot fluid valve port and the cold fluid valve port are respectively provided with a protruding edge. A reinforcing bar is connected between the heat insulation plate and the transfer arm. The heat insulation plate and the limiting plate are configured in an “L” shape. The heat insulation plate, the limiting plate, the reinforcing bar and the transfer arm are molded in one body.

In another aspect of the present invention, the mounting plate is provided with a hot fluid pipe and a cold fluid pipe. The hot fluid pipe is connected to the hot fluid entrance, and the cold fluid pipe is connected to the cold fluid entrance.

Compared with the prior art, the present invention has the following advantages: The present invention effectively improves the precision of retention station adjustment the rotor and the stator, as well as enhances the adjustment of a grouped assembly structure. Additionally, the present configuration increases the cold and hot conversion rate of the soft magnets, improves the utilization efficiency and the conversion efficiency of heat energy, while simplifying the structure of the rotor. Finally, the present invention simplifies the mold-making process, and improves assembly efficiency and the structural stability.

### BRIEF DESCRIPTION OF THE DRAWINGS

FIG. 1 is a breakdown structure diagram of the present invention.

FIG. 2 is a structure diagram of the main support of the present invention.

FIG. 3 is a breakdown structure diagram of the main support of the present invention from another viewing angle.

FIG. 4 is a structure diagram of the rotor of the present invention.

FIG. 5 is an enlarged structure diagram of part A in FIG. 4.

FIG. 6 is a structure diagram of the support body of the present invention.

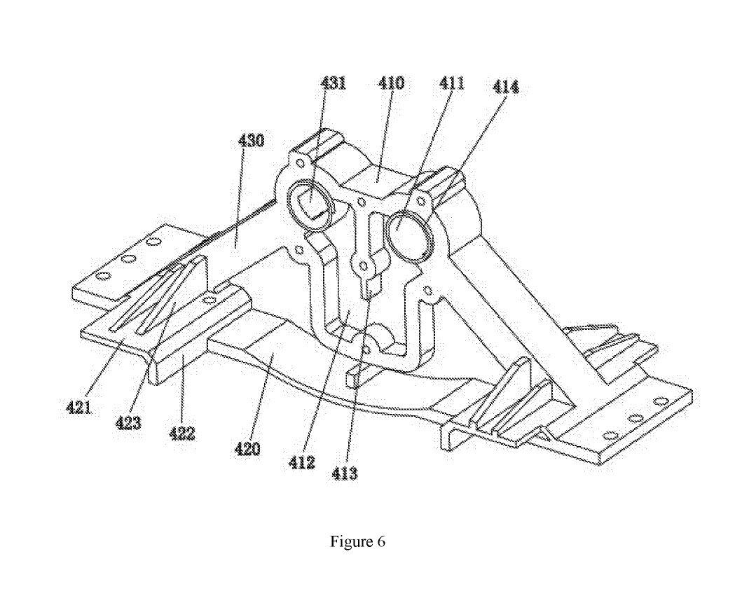

FIG. 7 is a structure diagram of the support body of the present invention from another viewing angle.

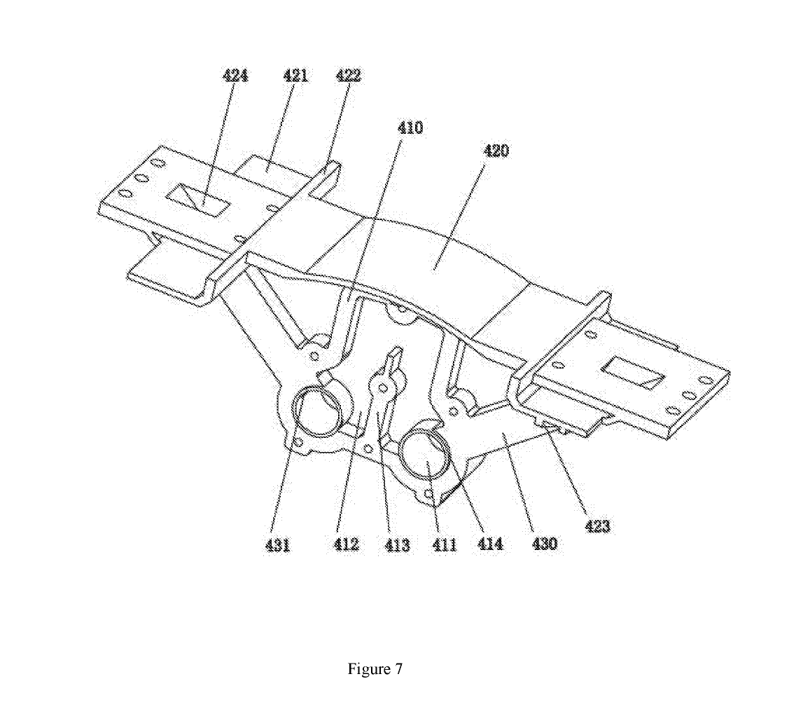

### MARKING INSTRUCTIONS OF THE DRAWINGS

100, Main Support; 110, Shaft Seat A; 120, Supporting Side Plate; 130, Connecting Plate; 131, Connecting Base; 132, Fluid Inlet; 133, Fluid Outlet; 134, Fluid Outlet; 140, Supporting Beam; 141, Adjusting Groove; 142, Guiding Plate; 143, Calibrated Scale; 150, Mounting Bracket; 151, Stationary Retention Magnet; 152, Locating Plate; 153, Fixing Screw Hole; 154, Adjusting Hole; 200, Rotor; 210, Shaft Seat B; 220, Annular Support; 230, Supporting Piece; 240, Hard Magnet Fixing Groove; 241, Outer Fixing Groove; 242, Inner Fixing Groove; 250, Magnet Locking Plate; 251, Mounting Hole; 260, Shielding Case; 270, Retention Hole; 300, Stator; 310, Fluid Inlet Pipe; 320, Fluid Outlet Pipe; 400, Heating and Cooling Device; 410, Support Body; 411, Fluid Valve Port; 412, Circulating Groove; 413, Flow-split Plate; 414, Protruding Edge; 420, Mounting Plate; 421, Heat Insulation Plate; 422, Limiting Plate, 423, Reinforcing Bar; 424, Fluid Entrance; 430, Transfer Arm; 431, Passage Hole; 440, Valve Cap; 441, Fluid Exit; 450, Fluid Pipe; 500, Dynamic Rotating Shaft.

### DETAILED DESCRIPTION OF THE INVENTION

Drawings and detailed embodiments are combined hereinafter to elaborate the technical principles of the present invention.

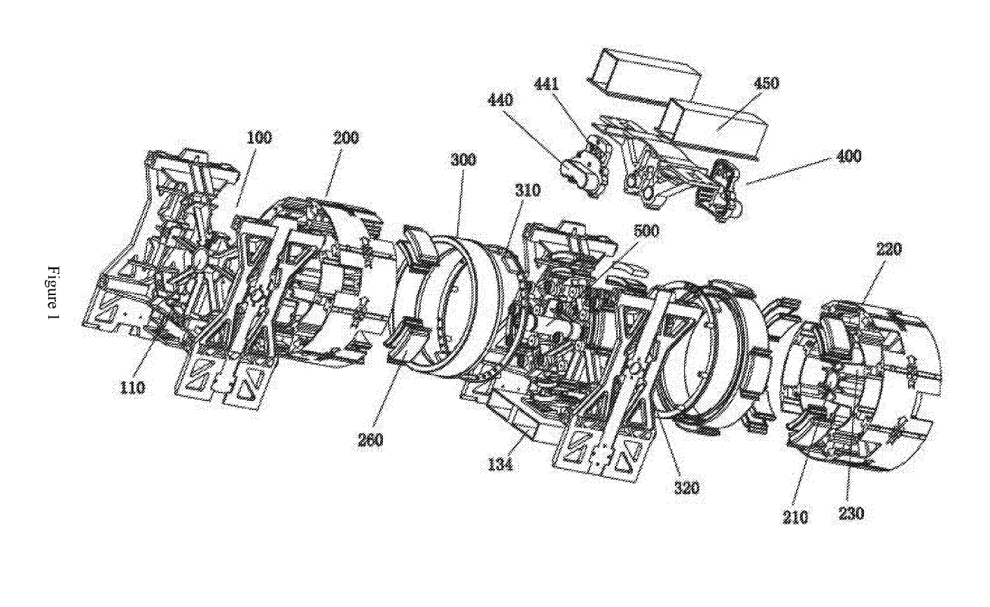

As shown in FIG. 1, the magnetic heat power generation device of the present invention comprises at least one magnetic heat power generation unit. The magnetic heat power generation unit comprises two main supports 100 that are correspondingly connected, and comprises a rotor 200, a stator 300 and a heating and cooling device 400. A shaft seat A110 is disposed on the main support 100, and a shaft seat B210 is disposed on the rotor 200. An accommodating chamber is formed between the two main supports 100, and the rotor 200 is disposed within the accommodating chamber. A dynamic rotation shaft 500 inserts into the shaft seat A110 and the shaft seat B210, enabling the rotor 200 to rotate within the accommodating chamber. The two stators 300 are fixed on the main supports 100 corresponding to the two sides of the rotor 200. The heating and cooling device 400 is fixed on the main supports 100. One end of the dynamic rotating shaft 500 is connected to the power generation equipment. The above forms the main structure of the present invention.

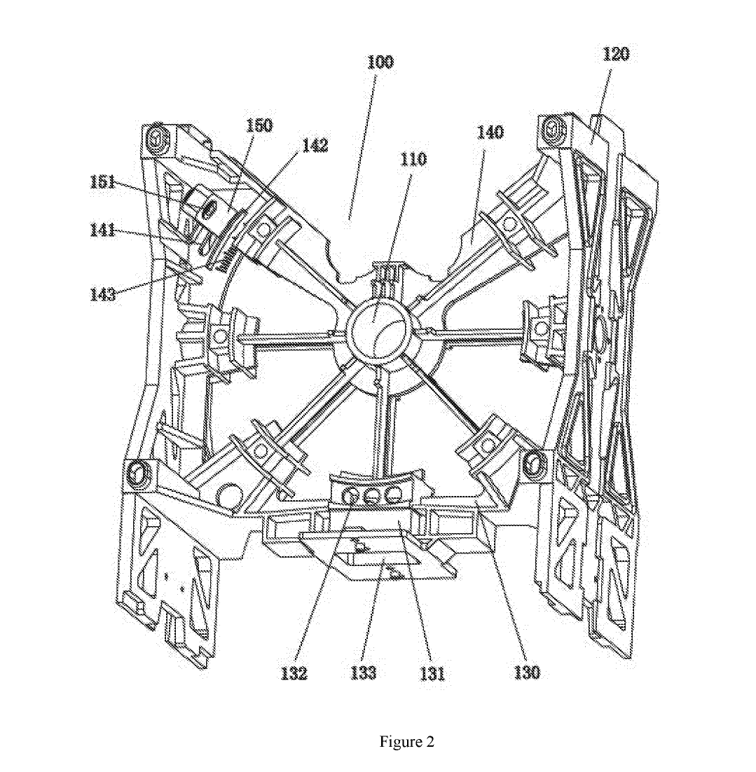

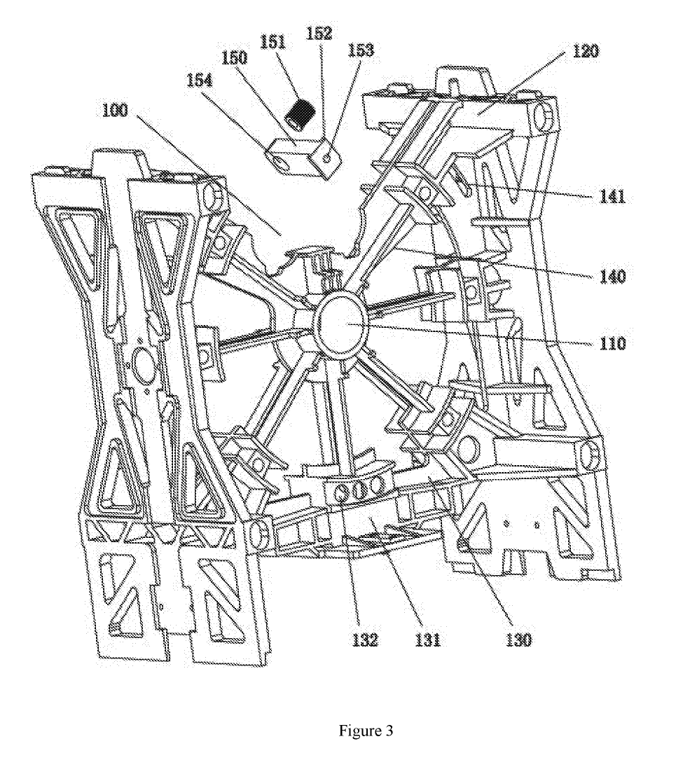

As shown in FIGS. 2 and 3, the main support 100 is part of the main structure of the present invention. The main support 100 comprises two side supporting plates 120 that are vertically disposed to correspond to each other. The lower portion of the two side supporting plates 120 are connected through a connecting plate 130. The shaft seat A110 is disposed in the middle of a space formed by the two side supporting plates 120 and the connecting plate 130. The shaft seat A110 is firmly connected to the side supporting plates 120 or the connection plate 130 through a plurality of supporting beams 140. The portion connecting one of the supporting beams 140 and the main support 100 is provided with an adjusting groove 141. A mounting bracket 150 is disposed in the adjusting groove 141. The mounting bracket 150 is provided with a stationary retention magnet 151. The outer edge of the rotor 200 is provided with a plurality of retention holes 270. Moving retention magnets are disposed in the retention holes 270. When a plurality of magnetic heat power generation units is assembled into a magnetic heat power generation device, any assembly error produced between the main supports 100 are corrected by regulating the mounting bracket 150, thereby adjusting the retention stations of the rotors 200 into a consistent state.

The adjusting groove 141, which is arc-shaped, takes the shaft seat A110 having the same plane as the center. The two sides of the inner and outer edges of the adjusting groove 141 are provided with guiding plates 142 corresponding to the radian of the adjusting groove 141. The two sides of the inner end of the mounting bracket 150 are provided with locating plates 152, and the outer side edges of the two locating plates 152 are respectively disposed against the guiding plate 142 on each side.

The supporting beam 140 having the adjusting groove 141 is provided with a calibrated scale 143 for interacting with the mounting bracket 150. When the mounting bracket 150 moves along the adjusting groove 141, the calibrated scale can be used as a reference to rapidly regulate and eliminate the assembly errors produced between the main supports 100. Consequently, the retention stations of the rotors 200 can be adjusted into a consistent state, thereby improving the initial torque of the rotors 200.

The inner end surface of the mounting bracket 150 is provided with a fixing screw hole 153. A fixing bolt is inserted into the adjusting groove 141. The front end of the fixing bolt is inserted through the adjusting groove 141 and connected to the fixing screw hole 153. An adjusting hole 154 is disposed on the mounting bracket 150, and the center of the adjusting hole 154 is on the radial line of the shaft seat A110 having the same plane. The stationary retention magnet 151, which is cylinder-shaped, is provided with outer threads for interacting with the adjusting hole 154. The stationary retention magnet 151 moves along the adjusting hole 154 to change the distance to the moving retention magnet on the rotor 200. Thus, the retention damping force of the rotor 200 can be changed; therefore, each rotor 200 outputs consistently and synchronously, improving the initial torque of the rotors 200.

During use, the mounting bracket 150 takes the shaft seat A110 as the center to rotate along the adjusting groove 141. The stationary retention magnet 151 on the mounting bracket 150 then interacts with any moving retention magnet on the rotor 200. Thus, the retention station of the rotor 200 in a stationary state can be changed. When a plurality of magnetic heat power generation units is assembled into a magnetic heat power generation device, the assembly errors produced between the main supports 100 can be corrected through regulating the mounting bracket 150, thereby achieving consistent retention stations of the rotors 200. Consequently, the initial torque of the rotors 200 can be greatly improved and the conversion rate of the magnetic heat power generation device can be effectively enhanced.

The connection plate 130 is provided with a connecting base 131, and a plurality of fluid inlets 132 is disposed on the upper portion of the connection base 131. The lower portion of the connecting base 131 is provided with a large-caliber fluid outlet 133, and the fluid outlet 133 is respectively interconnected to a plurality of fluid inlets 132. The lower end of the connecting base 131 is provided with a fluid outlet pipe 134 that is connected to the fluid outlet 133. A plurality of fluid inlet pipes 310 is disposed on the upper portion of the stator 300, and a plurality of fluid outlet pipes 320 is disposed on the lower portion of the stator 300. The fluid outlet pipes 320 are respectively connected to the fluid inlets 132 on the connecting base 131. The soft magnets on the stator 300 are heated and cooled by the heating and cooling device 400, thereby changing the magnetic field to propel the rotors 200 to rotate. The heating and cooling fluids are discharged from the fluid outlet pipes 320 after flowing through the stator 300, and enter into the fluid inlets 132 on the connecting base 131. Subsequently, the heating and cooling fluids are discharged from the large-caliber fluid outlet 133. By improving the flowing speed of the heating/cooling fluids, the soft magnets' temperature changing speed is significantly increased. Consequently, the heat conversion rate of the magnetic heat power generation device of the present invention can be greatly improved.

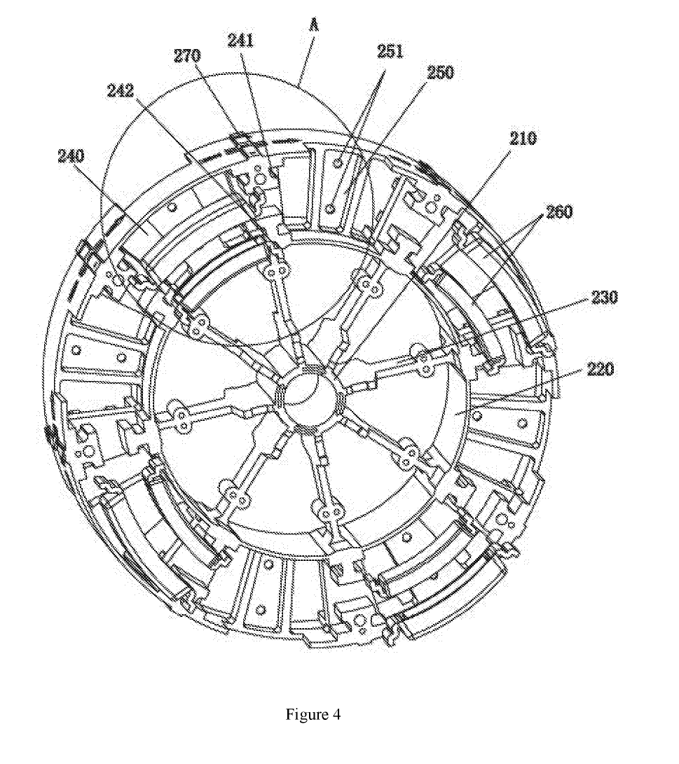

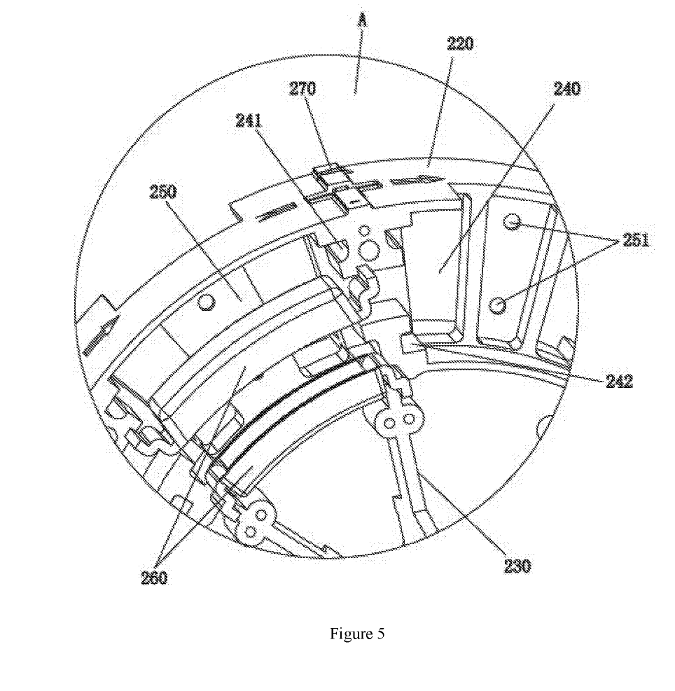

As shown in FIGS. 4 and 5, the rotor 200 comprises an annular support 220. The shaft seat B210, which is disposed in the annular support 220, is concentrically disposed with the annular-shaped support 220. A plurality of supporting pieces 230 is connected between the shaft seat B210 and the annular support 220. Even-numbered groups of hard magnet fixing grooves 240 are disposed on each of the two sides of the annular support 220, and the even number groups of hard magnet fixing grooves 240 are arranged in a staggered manner. A plurality of magnet locking plates 250 in one-to-one correspondence to the hard magnetic fixing grooves 240 is disposed on the annular support 220. The magnet locking plate 250 is provided with mounting holes 251, and a hard magnet shielding case 260 is disposed in the hard magnet fixing groove 240. A fixing bolt is inserted into the mounting hole 251 and connected to the hard magnet shielding case 260. A plurality of hard magnets on the rotor 200 is disposed into the corresponding hard magnet fixing grooves 240 through the shielding cases 260. The rear side of the magnet locking plate 250 is inserted into the fixing bolt and connected to the shielding case 260. In this arrangement, the connecting strength between the hard magnets and the annular support 220 can be improved, the mold-making process of the annular support 220 is simplified, and the assembly efficiency can be enhanced.

The magnet locking plate 250 is a grooved rail structure having a U-shaped cross section. The two ends of the magnet locking plate 250 are respectively connected to the inner wall and the outer wall of the annular support 220. The openings of the groove rail of any two adjacent magnet locking plates 250 are oppositely disposed. The magnet locking plates 250 in the same direction and the hard magnet fixing grooves 240 on one side of the annular support 220 are arranged in pairs. The fixing bolt is inserted into the open-slot of the rear side of the magnet locking plate 250, and connected to the shielding case 260. The head portion of the fixing bolt is recessed into the open-slot of the magnet locking plate 250. The magnet locking plate 250 having a U-shaped open slot is structurally stable and enhances the integral intensity of the rotor 200, thereby increases the design output power.

The hard magnet fixing groove 240 comprises an outer fixing groove 241 and an inner fixing groove 242. The outer fixing groove 241 and the inner fixing groove 242 are respectively provided with an outer shielding case 260 and an inner shielding case 260. The magnet locking plate 250 is provided with an inner mounting hole 251 and an outer mounting hole 251 that are disposed to correspond to the outer shielding case 260 and the inner shielding case 260. An accommodating space is formed between the outer fixing groove 241 and the inner fixing groove 242. The stator 300 is movably disposed in the accommodating space.

Moreover, the heating and cooling device 400 comprises a support body 410, a mounting plate 420 and two transfer arms 430. The lower end of the support body 410 is respectively connected to the lower ends of the two transfer arms 430. The two ends of the mounting plate 420 are respectively connected to the upper ends of the two transfer arms 430. Consequently, the upper end of the support body 410, the two ends of the mounting plate 420 and the two transfer arms 430 form a triangular configuration. The two sides of the portion connecting the mounting plate 420 and the transfer arm 430 are respectively provided with a heat insulation plate 421. A limiting plate 422 is disposed at the inner end of the heat insulation plate 421. The heat insulation plate 421 and the limiting plate 422 form an L-shaped configuration. The upper surface of the heat insulation plate 421 is lower than that of the mounting plate 420. Thus, the heat insulation plate 421 has a heat insulating layer separating the fluid pipe 450 from all components of the support body 410, thereby preventing the heating and cooling fluids in the heating and cooling device 400 from conducting heat with the outside environment. Further, each of the two sides of the support body 410 is provided with a valve cap 440. A plurality of fluid exits 441 is disposed on the valve cap 440. The fluid exits 441 on the valve cap 440 are respectively connected to the fluid inlet pipes 310 of the upper portion of the stator 300 on the corresponding side.

Furthermore, a hot fluid valve port 411, a cold fluid valve port 411 and a circulating groove 412 are formed on the support body 410. The portions connecting the mounting plate 420 and the two transfer arms 430 are respectively provided with a hot fluid entrance 424 and a cold fluid entrance 424. A passage hole 431 connecting the hot fluid valve port 411 and the hot fluid entrance 424, and a passage hole 431 connecting the cold fluid valve port 411 and the cold fluid entrance 424 are respectively formed on the two transfer arms. The circulating groove 412 is frame-shaped, and the hot fluid valve port 411 and the cold fluid valve port 411 are disposed at the two upper corners of the circulating groove 412. A flow-split plate 413 is disposed in the middle of the upper portion of the circulating groove 412. The opening ends of the hot fluid valve port 411 and the cold fluid valve port 411 are each provided with a protruding edge 414. A reinforcing bar 423 is connected between the heat insulation plate 421 and the transfer arm 430. The heat insulation plate 421 and the limiting plate 422 are configured in an “L” shape. The heat insulation plate 421, the limiting plate 422, the reinforcing bar 423 and the transfer arm are molded in one body.

The mounting plate 420 is provided with a hot fluid pipe 450 and a cold fluid pipe 450. The hot fluid pipe 450 is connected to the hot fluid entrance 424, and the cold fluid pipe 450 is interconnected to the cold fluid entrance 424.

The description of the above embodiments allows those skilled in the art to realize or use the present invention. Without departing from the spirit and essence of the present invention, those skilled in the art can combine, change or modify correspondingly according to the present invention. Therefore, the protective range of the present invention should not be limited to the embodiments above but conform to the widest protective range which is consistent with the principles and innovative characteristics of the present invention. Although some special terms are used in the description of the present invention, the scope of the invention should not necessarily be limited by this description. The scope of the present invention is defined by the claims.

1. A magnetic heat power generation device, comprising:
at least one magnetic heat power generation unit, wherein
the magnetic heat power generation unit comprises:
two main supports that are correspondingly connected;
a rotor;
a stator; and
a heating and cooling device, wherein a shaft seat A is disposed on the main support, and a shaft seat B is disposed on the rotor, wherein an accommodating chamber is formed between the two main supports, and the rotor is disposed within the accommodating chamber, wherein a dynamic rotation shaft inserts into the shaft seat A and the shaft seat B, enabling the rotor to rotate within the accommodating chamber, wherein the two stators are fixed on the main supports corresponding to the two sides of the rotor, wherein the heating and cooling device is fixed on the main supports, wherein one end of the dynamic rotating shaft is connected to the power generation equipment, wherein the rotor comprises an annular support, wherein the shaft seat B, which is disposed in the annular support, is concentrically disposed with the annular-shaped support, wherein a plurality of supporting pieces is connected between the shaft seat B and the annular support, wherein groups of hard magnet fixing grooves having an even number are disposed on each of the two sides of the annular support, wherein a plurality of magnet locking plates disposed in a one-to-one correspondence to the hard magnetic fixing grooves is disposed on the annular support, wherein each magnet locking plate is provided with mounting holes, and a hard magnet shielding case is disposed in the hard magnet fixing groove, wherein a fixing bolt is inserted into the mounting hole and connected to the hard magnet shielding case, wherein the main support comprises two side supporting plates that are vertically disposed to correspond to each other, wherein the lower portions of the two side supporting plates are connected through a connecting plate, wherein the shaft seat A is disposed in the middle of a space formed by the two side supporting plates and the connecting plate, wherein the shaft seat A is firmly connected to the side supporting plates or the connection plate through a plurality of supporting beams, wherein the portion connecting one of the supporting beams and the main support is provided with an adjusting groove, wherein a mounting bracket is disposed in the adjusting groove, wherein the mounting bracket is provided with a stationary retention magnet, wherein the outer edge of the rotor is provided with a plurality of retention holes, wherein moving retention magnets are disposed in the retention holes, wherein the connection plate is provided with a connecting base, and a plurality of fluid inlets is disposed on the upper portion of the connecting base, wherein the lower portion of the connecting base is provided with a large-caliber fluid outlet, and the fluid outlet is respectively connected to a plurality of fluid inlets, wherein the lower end of the connecting base is provided with a fluid outlet pipe that is connected to the fluid outlet, wherein a plurality of fluid inlet pipes is disposed on the upper portion of the stator, and a plurality of fluid outlet pipes is disposed on the lower portion of the stator, wherein the fluid outlet pipes are respectively connected to the fluid inlets on the connecting base, wherein the heating and cooling device comprises a support body, a mounting plate and two transfer arms, wherein the lower end of the support body is respectively connected to the lower ends of the two transfer arms, wherein the two ends of the mounting plate are respectively connected to the upper ends of the two transfer arms, wherein the upper end of the support body, the two ends of the mounting plate and the two transfer arms form a triangular configuration, wherein the two sides of the portion connecting the mounting plate and the transfer arms are respectively provided with a heat insulation plate, wherein a limiting plate is disposed at the inner end of the heat insulation plate, wherein each of the two sides of the support body is provided with a valve cap, wherein a plurality of fluid exits is disposed on the valve cap, and wherein the fluid exits on the valve cap are respectively connected to the fluid inlet pipes of the upper portion of the stator on the corresponding side.

2. The magnetic heat power generation device of claim 1, wherein the groups of hard magnet fixing grooves arranged in an even number are positioned in a staggered manner, wherein the magnet locking plate is a grooved rail structure having a U-shaped cross section, wherein the two ends of the magnet locking plate are respectively connected to the inner wall and the outer wall of the annular support, wherein the openings of the groove rails of any two adjacent magnet locking plates are oppositely disposed, and wherein the magnet locking plates in the same direction and the hard magnet fixing grooves on one side of the annular support are arranged in pairs.

3. The magnetic heat power generation device of claim 2, wherein the hard magnet fixing groove comprises:
an outer fixing groove, and
an inner fixing groove,
wherein the outer fixing groove and the inner fixing groove are respectively provided with an outer shielding case and an inner shielding case, wherein the magnet locking plate is provided with an inner mounting hole and an outer mounting hole that are disposed to correspond to the outer shielding case and the inner shielding case, wherein an accommodating space is formed between the outer fixing groove and the inner fixing groove, and wherein the stator is movably disposed in the accommodating space.

4. The magnetic heat power generation device of claim 1, wherein the adjusting groove, which is arc-shaped, takes the shaft seat A having the same plane as the center, and wherein the two sides of the inner and outer edges of the adjusting groove are provided with guiding plates corresponding to the radian of the adjusting groove, and wherein the two sides of the inner end of the mounting bracket are provided with locating plates, and the outer side edges of the two locating plates are respectively disposed against the guiding plate on each side.

5. The magnetic heat power generation device of claim 4, wherein the supporting beam having the adjusting groove is provided with a calibrated scale for interacting with the mounting bracket.

6. The magnetic heat power generation device of claim 4, wherein the inner end surface of the mounting bracket is provided with a fixing screw hole, wherein a fixing bolt is inserted into the adjusting groove, and wherein the front end of the fixing bolt is inserted through the adjusting groove and connected to the fixing screw hole, wherein an adjusting hole is disposed on the mounting bracket, and the center of the adjusting hole is on the radial line of the shaft seat A having the same plane, and wherein the stationary retention magnet, which is cylinder-shaped, is provided with outer threads for interacting with the adjusting hole.

7. The magnetic heat power generation device of claim 1, wherein a hot fluid valve port, a cold fluid valve port and a circulating groove are formed on the support body, wherein the portions connecting the mounting plate and the two transfer arms are respectively provided with a hot fluid entrance and a cold fluid entrance, and wherein a passage hole connecting the hot fluid valve port and the hot fluid entrance, and a passage hole connecting the cold fluid valve port and the cold fluid entrance are respectively formed on the two transfer arms.

8. The magnetic heat power generation device of claim 7, wherein the circulating groove is frame-shaped, and the hot fluid valve port and the cold fluid valve port are respectively disposed at the two upper corners of the circulating groove, and wherein a flow-split plate is disposed in the middle of the upper portion of the circulating groove.

9. The magnetic heat power generation device of claim 7, wherein the opening ends of the hot fluid valve port and the cold fluid valve port are respectively provided with a protruding edge, wherein a reinforcing bar is connected between the heat insulation plate and the transfer arm, wherein the heat insulation plate and the limiting plate are configured in an “L” shape, and wherein the heat insulation plate, the limiting plate, the reinforcing bar and the transfer arm are molded in one body.

10. The magnetic heat power generation device of claim 7, wherein the mounting plate is provided with a hot fluid pipe and a cold fluid pipe, and wherein the hot fluid pipe is connected to the hot fluid entrance, and the cold fluid pipe is connected to the cold fluid entrance.
